(19) United States
(12) Patent Application Publication
(10) Pub. No.: US 2010/0037823 A1
(43) Pub. Date: Feb. 18, 2010

(54) SHOWERHEAD AND SHADOW FRAME

(75) Inventors: TOM K. CHO, Los Altos, CA (US); Zheng Yuan, Cupertino, CA (US); Brian Sy-Yuan Shieh, Palo Alto, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/537,278

(22) Filed: Aug. 7, 2009

Related U.S. Application Data
(60) Provisional application No. 61/089,825, filed on Aug. 18, 2008.

(51) Int. Cl. C23C 16/00; B05B 1/14

(52) U.S. Cl. 118/723 R; 239/548

(57) ABSTRACT

The present invention generally relates to a gas distribution showerhead and a shadow frame for an apparatus. By extending the corners of the gas distribution showerhead the electrode area may be expanded relative to the anode and thus, uniform film properties may be obtained. Additionally, the expanded corners of the gas distribution showerhead may have gas passages extending therethrough. In one embodiment, hollow cathode cavities may be present on the bottom surface of the showerhead without permitting gas to pass therethrough. The shadow frame in the apparatus may also have its corner areas extended out to enlarge the anode in the corner areas of the substrate being processed and thus, may lead to deposition of a material on the substrate having substantially uniform properties.

### CROSS-REFERENCE TO RELATED APPLICATIONS

This application claims benefit of U.S. provisional patent application Ser. No. 61/089,825, filed Aug. 18, 2008, which is herein incorporated by reference.

### BACKGROUND OF THE INVENTION

1. Field of the Invention

Embodiments of the present invention generally relate to a gas distribution showerhead, a shadow frame, and an apparatus for processing a substrate.

2. Description of the Related Art

Plasma enhanced chemical vapor deposition (PECVD) is a deposition method whereby processing gas is introduced into a processing chamber through a gas distribution showerhead. The showerhead is electrically biased to ignite the processing gas into a plasma. The susceptor, sitting opposite to the showerhead, is electrically grounded and functions as an anode. The showerhead spreads out the processing gas as it flows into the processing space between the showerhead and the susceptor.

PECVD has recently become popular for depositing material onto large area substrates. Large area substrates may have a surface area of greater than about one square meter. Large area substrates may be used for flat panel displays (FPDs), solar panels, organic light emitting displays (OLEDs), and other applications.

In addition to the showerhead and susceptor, a shadow frame may be present within the apparatus. The shadow frame may be used to cover the edges of the substrate, if desired, and the edges of the susceptor that are not covered by the substrate. The shadow frame may reduce deposition of material on the susceptor. In the absence of a shadow frame, material may deposit on the susceptor edges and potentially bridge to the substrate.

When material bridges to the substrate, the substrate and material deposited thereon may be damaged when the bridge is broken. Additionally, when material is deposited onto the susceptor, flaking of the material may occur or potentially, the substrate may be misaligned due to an uneven susceptor surface. Misalignment of the substrate may cause uneven deposition.

Due to the increased use of PECVD, there is a need for gas distribution showerheads and shadow frames.

### SUMMARY OF THE INVENTION

The present invention generally relates to a gas distribution showerhead and a shadow frame for an apparatus. By extending the corners of the gas distribution showerhead, the electrode area may be expanded relative to the anode and thus, uniform film properties may be obtained. Additionally, the expanded corners of the gas distribution showerhead may have gas passages extending therethrough. In one embodiment, hollow cathode cavities may be present on the bottom surface of the showerhead without permitting gas to pass therethrough. The shadow frame in the apparatus may also have its corner areas extended out to enlarge the anode in the corner areas of the substrate being processed and thus, may lead to deposition of a material on the substrate having substantially uniform properties.

In one embodiment, a gas distribution showerhead includes a showerhead body having a generally rectangular shape with a plurality of gas passages extending therethrough and one or more elements extending from one or more corners of the showerhead body.

In another embodiment, a gas distribution showerhead includes a showerhead body having a generally rectangular shape and a plurality of gas passages extending therethrough. One or more cutouts may be carved in one or more sides of the showerhead body such that at least a portion of the one or more sides having the one or more cutouts extends beyond the one or more cutouts at one or more corners of the showerhead body.

In another embodiment, a gas distribution showerhead includes a showerhead body having a generally rectangular shape with four sides each having a length and four corners. At least one corner of the four corners has one or more flanges extending from the corner along a length of a side for a length less than the side length.

In another embodiment, an apparatus includes a chamber body, a susceptor disposed within the chamber body, and a gas distribution showerhead. The susceptor has a first surface area. The showerhead is disposed in the chamber body opposite the susceptor facing the side of the susceptor having the first surface area. The gas distribution showerhead has a second surface area greater than the first surface area.

In another embodiment, an apparatus includes a chamber body, a susceptor disposed in the chamber body and having a generally rectangular shape and four sides, and a gas distribution showerhead having a plurality of gas passages extending therethrough. The gas distribution showerhead has a generally rectangular shaped body having four sides substantially aligned with each of the four sides of the susceptor. The corners of the gas distribution showerhead are not substantially aligned with the corners of the susceptor.

In another embodiment, an apparatus includes a chamber body having a generally rectangular shape, a susceptor disposed in the chamber body having a generally rectangular shape, and a gas distribution showerhead disposed in the chamber body opposite the susceptor. The gas distribution showerhead has a generally rectangular shape and at least one corner that extends closer to a corner of the chamber body than any corner of the susceptor extends to any corner of the chamber body.

In another embodiment, an apparatus includes a chamber body having a generally rectangular shape, a susceptor disposed in the chamber body having a generally rectangular shape, a gas distribution showerhead disposed in the chamber body opposite the susceptor, and a shadow frame disposed in the chamber body between the susceptor and the gas distribution showerhead. The shadow frame has at least one corner that extends closer to a corner of the chamber body than any corner of the susceptor or showerhead extends to any corner of the chamber body.

In another embodiment, a gas distribution showerhead includes a showerhead body having an upstream surface and a downstream surface with a plurality of gas passages extending between the upstream surface and the downstream surface. The showerhead body also has one or more cavities in the downstream surface separate from the gas passages.

In another embodiment, a gas distribution showerhead is disclosed. The gas distribution showerhead includes a showerhead body having a generally rectangular shape, a first surface, a second surface opposite to the first surface, and a plurality of gas passages extending between the first surface and the second surface. The gas distribution showerhead also includes one or more corner extension elements coupled to the showerhead body and extending from one or more corners of the showerhead body, the one or more corner extension elements having a third surface and a fourth surface opposite the third surface.

In another embodiment, a plasma enhanced chemical vapor deposition apparatus is disclosed. The apparatus includes a chamber body and a substrate support disposed within the chamber body having a substrate support surface for receiving a substrate. The substrate support surface has a generally rectangular shape. The apparatus also includes a gas distribution showerhead disposed in the chamber body opposite the substrate support. The gas distribution showerhead has a first surface facing the substrate support surface and a second surface opposite the first surface. The first surface generally mirrors the substrate support surface. The apparatus also includes one or more showerhead extension elements coupled to the gas distribution showerhead at one or more corners thereof.

In another embodiment, a plasma enhanced chemical vapor deposition apparatus is disclosed. The apparatus includes a chamber body having a generally rectangular shape and a substrate support disposed in the chamber body having a generally rectangular shape. The apparatus also includes a gas distribution showerhead disposed in the chamber body opposite the susceptor. The apparatus may also include a shadow frame disposed in the chamber body between the substrate support and the gas distribution showerhead. The shadow frame has a main body that has a generally rectangular shape and one or more corner extension elements that extend from one or more corners of the main body.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a PECVD apparatus according to one embodiment.

FIG. 2A is a schematic top view of a solar cell structure according to one embodiment.

FIG. 2B is a schematic cross sectional view of the solar cell structure of FIG. 2A.

FIG. 2C is a schematic cross sectional view of a solar cell structure according to another embodiment.

FIG. 3A is a schematic top view of a gas distribution showerhead according to one embodiment.

FIG. 3B is a schematic top view of a gas distribution showerhead according to another embodiment.

FIG. 3C is a schematic bottom view of a gas distribution showerhead according to one embodiment.

FIG. 3D is a schematic bottom view of a gas distribution showerhead according to another embodiment.

FIG. 4 is a schematic cross sectional view of a PECVD apparatus 400 according to another embodiment.

FIG. 5A is a schematic top view of a showerhead that shows where the cross section is taken for FIGS. 5B and 5C along line H-H.

FIG. 5B is a schematic cross sectional view of a showerhead 500 according to one embodiment.

FIG. 5C is a schematic cross sectional view of a showerhead 550 according to another embodiment.

FIG. 6 is a schematic cross sectional view of a gas passage 602 in a showerhead 600 according to one embodiment.

FIG. 7 is a schematic cross sectional view of a PECVD apparatus 700 according to another embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present invention generally relates to a gas distribution showerhead and a shadow frame for an apparatus. By extending the corners of the gas distribution showerhead, the electrode area may be expanded relative to the anode and thus, uniform film properties may be obtained. Additionally, the expanded corners of the gas distribution showerhead may have gas passages extending therethrough. In one embodiment, hollow cathode cavities may be present on the bottom surface of the showerhead without permitting gas to pass therethrough. The shadow frame in the apparatus may also have its corner areas extended out to enlarge the anode in the corner areas of the substrate being processed and thus, may lead to deposition of a material on the substrate having substantially uniform properties.

The invention will be described below in relation to a PECVD apparatus available from AKT America, Inc., a subsidiary of Applied Materials, Inc., Santa Clara, Calif. It is to be understood that the invention has applicability in other chambers as well, including PECVD apparatus available from other manufacturers.

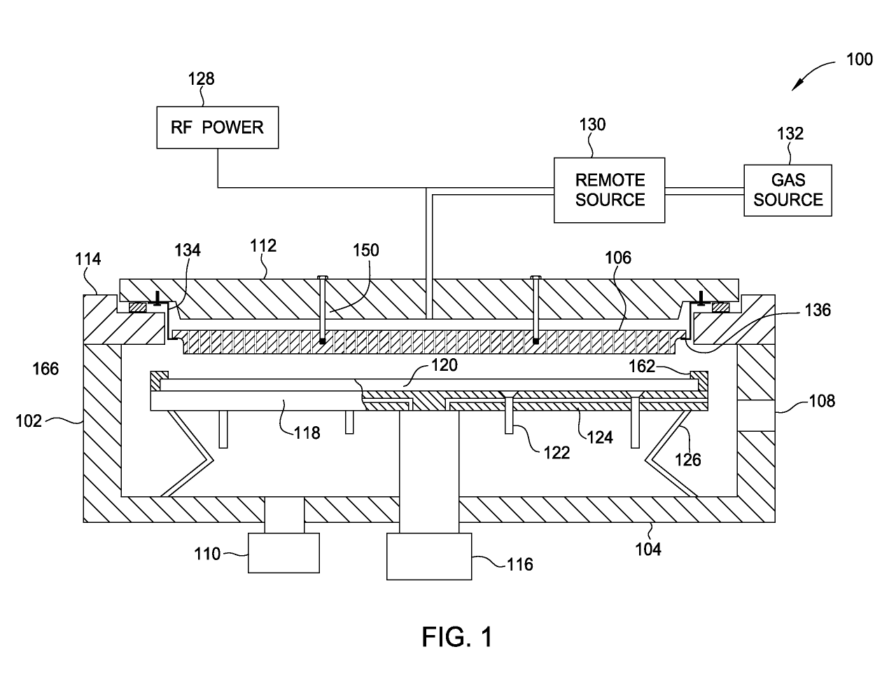

FIG. 1 is a cross sectional view of a PECVD apparatus according to one embodiment of the invention. The PECVD apparatus includes a chamber 100 having walls 102 and a bottom 104. A showerhead 106 and susceptor 118 are disposed in the chamber 100 and bound a process volume therebetween. The process volume is accessed through a slit valve opening 108 such that the substrate 120 may be transferred in and out of the chamber 100. In one embodiment, the substrate 120 may have a rectangular shape. The susceptor 118 may be coupled to an actuator 116 to raise and lower the susceptor 118. Lift pins 122 are moveably disposed through the susceptor 118 to support a substrate 120 prior to placement onto the susceptor 118 and after removal from the susceptor 118. The susceptor 118 may also include heating and/or cooling elements 124 to maintain the susceptor 118 at a desired temperature.

Grounding straps 126 may be coupled to the susceptor 118 to provide RF grounding at the periphery of the susceptor 118. The grounding straps 126 may be coupled to the bottom 104 of the chamber 100. In one embodiment, the grounding straps 126 may be coupled to the corners of the susceptor 118 and the bottom 104 of the chamber 100.

The showerhead 106 is coupled to a backing plate 112 by a coupling 144. In one embodiment, the coupling 144 may comprise a bolt threadedly engaged with the showerhead 106. The showerhead 106 may be coupled to the backing plate 112 by one or more couplings 144 to help prevent sag and/or control the straightness/curvature of the showerhead 106. In one embodiment, twelve couplings 144 may be used to couple the showerhead 106 to the backing plate 112. The showerhead 106 may additionally be coupled to the backing plate 112 by a bracket 134. The bracket 134 may have a ledge 136 upon which the showerhead 106 may rest. The backing plate 112 may rest on a ledge 114 coupled with the chamber walls 102 to seal the chamber 100.

The spacing between the top surface of the substrate 120 and the showerhead 106 may be between about 400 mil and about 1,200 mil. In one embodiment, the spacing may be between about 400 mil and about 800 mil.

A gas source 132 is coupled to the backing plate 112 to provide gas through gas passages in the showerhead 106 to the substrate 120. A vacuum pump 110 is coupled to the chamber 100 at a location below the susceptor 118 to maintain the process volume at a predetermined pressure. A RF power source 128 is coupled to the backing plate 112 and/or to the showerhead 106 to provide a RF power to the showerhead 106. The RF power creates an electric field between the showerhead 106 and the susceptor 118 so that a plasma may be generated from the gases between the showerhead 106 and the susceptor 118. Various frequencies may be used, such as a frequency between about 0.3 MHz and about 200 MHz. In one embodiment, the RF power is provided at a frequency of 13.56 MHz. In one embodiment, an AC power source may be coupled to the showerhead 106. In another embodiment, the chamber 100 is a parallel plate PECVD chamber.

A remote plasma source 130, such as an inductively coupled remote plasma source, may also be coupled between the gas source 132 and the backing plate 112. Between processing substrates, a cleaning gas may be provided to the remote plasma source 130 so that a remote plasma is generated. Radicals from the remotely generated plasma may then be provided to the chamber 100 to clean components of the chamber 100. The cleaning gas may be further excited by power provided by the RF power source 128 to the showerhead 106. Suitable cleaning gases include but are not limited to NF₃, F₂, and SF₆.

A shadow frame 162 may be present within the chamber 100. The shadow frame 162 prevents deposition from occurring on the edges of the substrate support 106 that are not covered by the substrate 120. Additionally, the shadow frame 162 may prevent deposition from occurring on the edges of the substrate 120. The shadow frame 162 may be spaced from the substrate 120 such that material that deposits on the substrate 120 may not bridge to the shadow frame 162. Additionally, the shadow frame 162 is coupled to the susceptor 118 by a coupling. The susceptor 118, as it raises to the processing position, may come into contact with the shadow frame 162 and raise it along with the susceptor 118 and substrate 120. The coupling may be an alignment pin that properly aligns the shadow frame 162 on the susceptor 118 without fixedly coupling the shadow frame 162 to the susceptor 118. The shadow frame 162, by being coupled to the susceptor 118, may be part of the RF return path, which is sometimes referred to as RF grounded. Additionally, the shadow frame 162 creates a pumping plenum between the shadow frame 162 and the chamber walls 102.

The chamber 100 is suitable for chemical vapor deposition (CVD) or PECVD processes for fabricating a solar panel, an OLED, or the circuitry of an FPD on a large area glass, polymer, or other suitable substrate. The structures produced may be thin film transistors (TFTs) which may comprise a plurality of sequential deposition and masking steps. Other structures may include p-n junctions to form diodes for photovoltaic cells.

The chamber 100 is configured to deposit a variety of materials on a large area substrate that includes conductive materials (e.g., ITO, ZnO₂, W, Al, Cu, Ag, Au, Ru or alloys thereof), dielectric materials (e.g., Si, SiO₂, SiOₓN_{y}, HfO₂, HfSiO₄, ZrO₂, ZrSiO₄, TiO₂, Ta₂O₅, Al₂O₃, derivatives thereof or combinations thereof), semiconductive materials (e.g., Si, Ge, SiGe, dopants thereof or derivatives thereof), barrier materials (e.g., SiNₓ, SiOₓN_{y}, Ti, TiNₓ, TiSiₓN_{y}, Ta, TaNₓ, TaSiₓN_{y} or derivatives thereof) and adhesion/seed materials (e.g., Cu, Al, W, Ti, Ta, Ag, Au, Ru, alloys thereof and combinations thereof). In one embodiment, the chamber 100 is used to deposit a layer of microcrystalline silicon.

Metal-containing compounds that may be deposited in the chamber 100 include metals, metal oxides, metal nitrides, metal silicides, or combinations thereof. For example, metal-containing compounds include tungsten, copper, aluminum, silver, gold, chromium, cadmium, tellurium, molybdenum, indium, tin, zinc, tantalum, titanium, hafnium, ruthenium, alloys thereof, or combinations thereof. Specific examples of conductive metal-containing compounds that are formed or deposited in the chamber 100 onto the large area substrates, such as gate electrodes and other conductive layers, include indium tin oxide, zinc oxide, tungsten, copper, aluminum, silver, derivatives thereof or combinations thereof.

The chamber 100 is also configured to deposit dielectric materials and semiconductive materials in a polycrystalline, amorphous or epitaxial state. For example, dielectric materials and semiconductive materials may include silicon, germanium, carbon, oxides thereof, nitrides thereof, dopants thereof or combinations thereof. Specific examples of dielectric materials and semiconductive materials that are formed or deposited by the chamber 100 onto the large area substrates may include epitaxial silicon, polycrystalline silicon, amorphous silicon, silicon germanium, germanium, silicon dioxide, silicon oxynitride, silicon nitride, dopants thereof (e.g., B, P or As), derivatives thereof or combinations thereof.

The chamber 100 is also configured to receive gases such as argon, hydrogen, nitrogen, helium, or combinations thereof, for use as a purge gas or a carrier gas (e.g., Ar, H₂, N₂, He, derivatives thereof, or combinations thereof). One example of depositing amorphous silicon thin films on a large area substrate using the chamber 100 may be accomplished by using silane as the precursor gas in a hydrogen carrier gas.

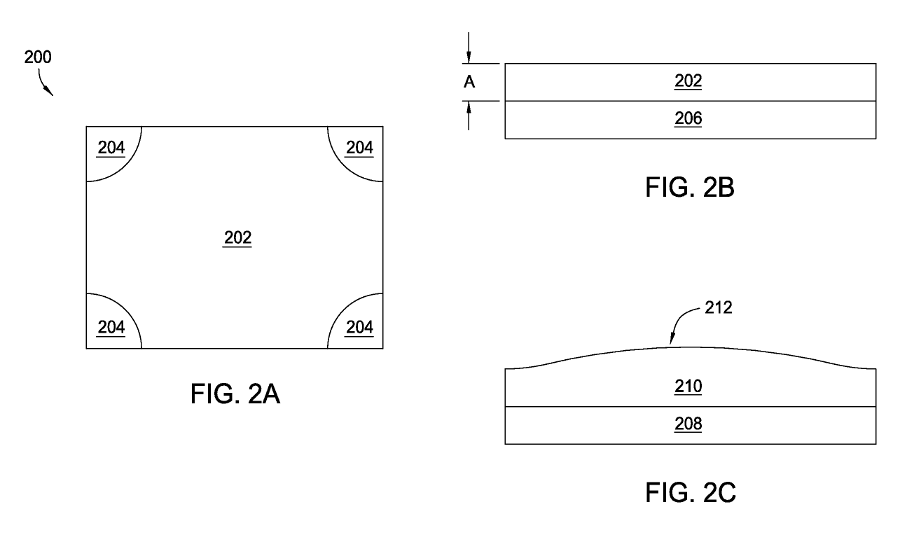

FIG. 2A is a schematic top view of a solar cell structure 200 according to one embodiment of the invention. FIG. 2B is a schematic cross sectional view of the solar cell structure 200 of FIG. 2A. When forming a solar cell structure 200, microcrystalline silicon is sometimes used. However, when depositing microcrystalline silicon over a large area substrate, it may be difficult to obtain a consistent layer across the substrate. As shown in FIG. 2A, the layer deposited on the solar cell structure 200 may have microcrystalline silicon in the center area 202 and at the edges, but at the corners 204, the silicon is amorphous. Thus, while the material is deposited to a uniform thickness as shown by arrow “A” as shown in FIG. 2B, the desired film of microcrystalline silicon has not been deposited. Additionally, the microcrystalline silicon may not have substantially identical properties throughout the layer. The microcrystalline silicon properties may gradually change from the center of the layer to the corner of the layer where the amorphous silicon is present.

To ensure microcrystalline silicon formation rather than amorphous silicon formation, a greater amount of silicon precursor gas may be introduced into the processing chamber. Additionally, a high RF current may be applied to the gas distribution showerhead. The higher power and/or higher precursor flow may increase the formation of microcrystalline silicon. As shown in FIG. 2C, the material layer 210 formed over the substrate 208 is microcrystalline silicon throughout the layer, but a greater amount of material is deposited in the center area 212 of the substrate as compared to the edges. Thus, simply increasing the flow of precursor gas and/or increasing the RF current to the showerhead may not lead to a uniformly thick microcrystalline silicon layer. However, increasing the flow of precursor gas and/or the RF current to the showerhead may increase the formation of microcrystalline silicon.

When the showerhead has a rectangle shape, the corners of the rectangle are close to two walls of the chamber that meet to form the corner of the chamber. The walls of the chamber are part of the RF return path, which may be referred to as RF grounded by some in industry, and act as an anode in opposition to the electrically biased showerhead. Thus, the wall effect in the corners may be about double the wall effect at all other areas of the showerhead. Due to the increased wall effect near the corners, the plasma near the corners may not have the same properties as the plasma at other locations in the chamber. The non-uniform plasma may lead to different properties in the layer deposited. Thus, the corner areas of the substrate may have amorphous silicon while the remainder of the substrate may have microcrystalline silicon. The plasma may also have a standing wave effect that may be greater in the corner areas of the chamber which may also contribute to the non-uniform plasma.

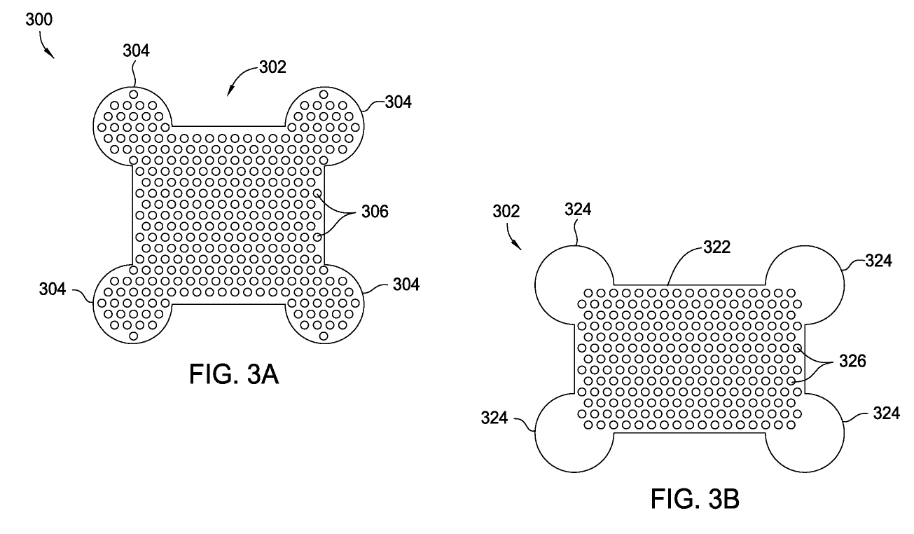

One manner to ensure microcrystalline silicon formation while also depositing a layer having a uniform thickness is to adjust the shape of the gas distribution showerhead. FIG. 3A is a schematic top view of a gas distribution showerhead 300 according to one embodiment of the invention. The showerhead 300 has a rectangular area 302 and corners 304. A plurality of gas passages 306 extend through the showerhead 300. As can be seen from FIG. 3A, the corners 304 extend beyond the rectangular area 302. Hence, the electrode, which the showerhead 300 is when electrically biased with an RF current, is extended further outward from the rectangular area 302.

The processing chamber in which the showerhead 300 will be placed may still retain a rectangular shape. The areas between the corners 304 may be left open if desired or filled with a material to prevent plasma formation in those locations. In one embodiment, the filler material may comprise ceramic and be coupled to the chamber walls.

Gas passages 306 may be present in both the rectangular areas 302 as well as the corner areas 304. The gas passages in the corner areas increase the flow of processing gas (or cleaning radicals when in cleaning mode) to the corner areas of the chamber and hence, may increase the amount of material deposited on the substrate in the corner areas. Additionally, the increased processing gas flow to the corner areas of the chamber and/or the increased electrode area in the corner areas of the chamber may ensure that the material deposited on the substrate has consistent properties throughout the layer. The gas passages 306 may be arranged in a closed pack pattern.

FIG. 3B is a schematic top view of a gas distribution showerhead 320 according to another embodiment of the invention. The showerhead 320 has the rectangular area 322 and the corners 324 that are extended, but the gas passages 326 are present only in the rectangular area 322. The gas passages may be present only in the rectangular area 322 because of the optimized gas flow. When the gas flow necessary to deposit a uniform thickness film is known for the rectangular area 322, the corners 324, if gas passages are present, would affect the optimized gas distribution. Thus, gas passages through the corners 324 may adversely affect the gas distribution if the gas distribution is already known.

By extending the corners 324 of the showerhead 320 without having gas passages 326 through the corners 324, the electrode is extended out, but the gas flow is not extended closer to the corners of the chamber. However, the plasma formed near in the rectangular area 322 is further away from the chamber walls than it would otherwise be in absence of the corners 324. Thus, the plasma in the rectangular area 322 may be more uniformly distributed because the corner of the chamber is further away from the rectangular area 322 than they would otherwise be in absence of the corners 324. Therefore, the plasma is further away from the chamber walls and may permit a more uniform layer, in terms of the layer properties, to be deposited. The gas passages 326 may be arranged in a closed pack pattern.

FIG. 3C is a schematic bottom view of a gas distribution showerhead 340 according to one embodiment of the invention. The showerhead 340 may have a rectangular area 342 as well as corners 344 that extend out from the rectangular area 342 towards the corners of the chamber. Gas passages 346 are present in both the rectangular area 342 as well as the corners 344. In one embodiment, the gas passages 346 in the corners 344 extend all the way through the showerhead 340. In another embodiment, the gas passages 346 in the corners 344 do not extend through the showerhead 340. The gas passages 346 may be arranged in a closed pack pattern.

FIG. 3D is a schematic bottom view of a gas distribution showerhead 360 according to another embodiment of the invention. The showerhead 360 has a rectangular area 362 and corners 362 that extend out from the rectangular area 362 towards the corner of the chamber. Gas passages 366 may pass through the showerhead 360 in the rectangular area 362, but not in the corners 364 that extend beyond the rectangular area 362. The gas passages 366 may be arranged in a closed pack pattern.

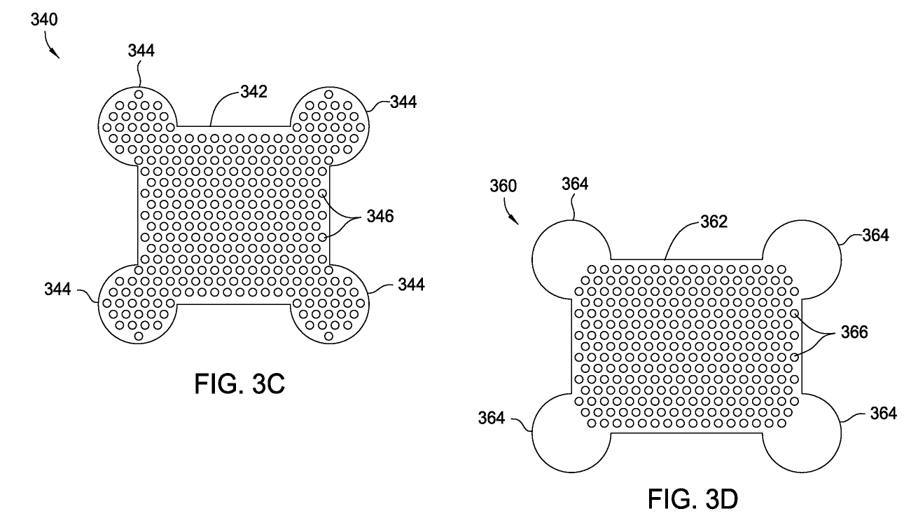

FIG. 4 is a schematic cross sectional view of a PECVD apparatus 400 according to another embodiment of the invention. FIG. 4 shows the view looking up at the showerhead 408. The chamber components below the showerhead 408 have been removed for clarity. The susceptor (not shown) may have a shape that mirrors the showerhead 408. The apparatus 400 have a chamber body having a generally rectangular shape. The chamber body has four walls 402 that meet for form four corners 404. The showerhead 408 may have a rectangular area 412 and four corners 410 that extend out from the rectangular area 412 towards the corners 404 of the chamber body. In the areas between the corners 410 of the showerhead 408, filler material 406 may be present and extend from the chamber walls 402. In one embodiment, the filler material 406 may comprise a dielectric material. In another embodiment, the filler material 406 may comprise ceramic material. Because the filler material 406 is coupled to the walls 402, the filler material 406 is electrically grounded. A plurality of gas passages 414 may extend through the showerhead 408 in the rectangular area 412. In the embodiment shown in FIG. 4, gas passages 414 are not present in the corners 410 of the showerhead 408. The gas passages 414 may be arranged in a closed pack pattern.

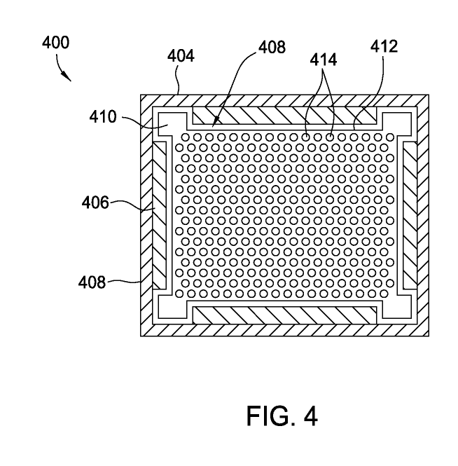

FIG. 5A is a schematic top view of a hypothetic showerhead that shows where the cross section is taken for FIGS. 5B and 5C along line H-H. FIG. 5B is a schematic cross sectional view of a showerhead 500 according to one embodiment of the invention. The showerhead 500 has a plurality of gas passages 502 extending therethrough. As shown in FIG. 5B, the gas passages 502 extend through the showerhead 500 from the upstream side 504 to the downstream side 506. The gas passages may be present in both the rectangular area of the showerhead 500 represented by arrows “D” and also in the corner areas of the showerhead 500 represented by arrows “B” and “C”. While not shown, the rectangular area may have a concave surface for the downstream side 506. Additionally, the corner areas may have a substantially planar surface that is parallel to the upstream planar surface.

FIG. 5C is a schematic cross sectional view of a showerhead 550 according to another embodiment of the invention. The showerhead has a plurality of gas passages 552 that pass between the upstream surface 554 and the downstream surface 556 in the rectangular area of the showerhead 550. The rectangular area of the showerhead 550 is represented by arrows “G”. The corners of the showerhead 550 that extend beyond the rectangular area have hollow cathode cavities 558 on the downstream side 556 of the showerhead 550, but the hollow cathode cavities 558 do not couple with gas passages and hence, do not extend through the showerhead 550 at the corner extensions. Similar to FIG. 5B, the showerhead 550 may have a concave downstream surface 556 in the rectangular area and a planar downstream surface 556 in the corners. In another embodiment, a blocker plate may be used to prevent gas from flowing through the gas passages 522 in the corner extensions of the showerhead 550.

The hollow cathode cavities 558 provide an area within the showerhead 550 where a plasma may ignite. When there are no gas passages in the corner extensions, one would not normally expect any plasma to ignite within the corner extensions because no gas is flowing therethrough. However, by having hollow cathode cavities 558 in the corner extensions, the gas, as is disperses within the chamber, comes into contact with the hollow cathode cavities 558 that are in the corner extensions and thus, ignite into a plasma within the hollow cathode cavities 558. The hollow cathode cavities 558 may alter the shape of the plasma and the plasma density within the processing chamber during operation. In one embodiment, the corner extensions may have straight gas passages without any hollow cathode cavities while the rectangular area of the showerhead 550 may have hollow cathode cavity type gas passages.

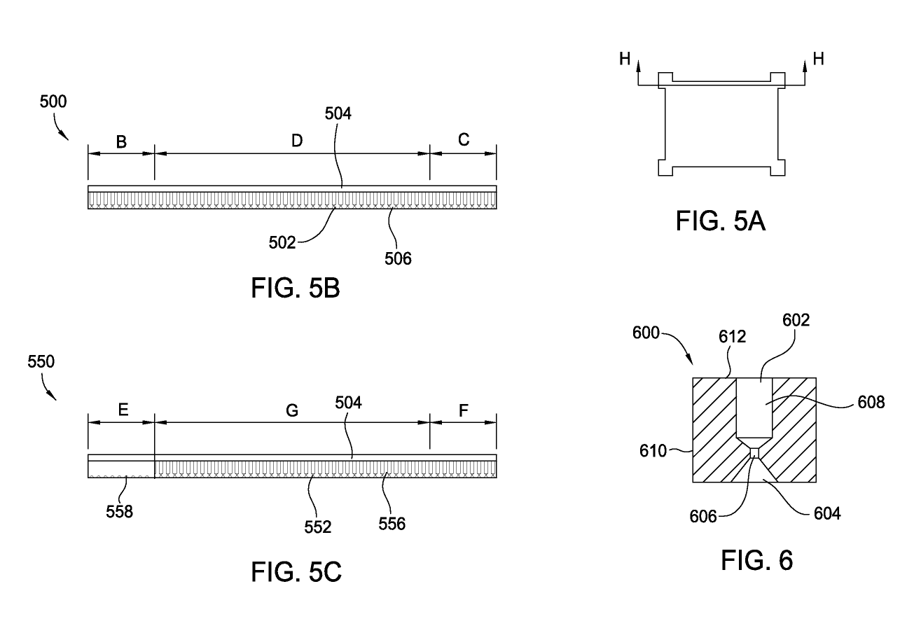

FIG. 6 is a schematic cross sectional view of a gas passage 602 in a showerhead 600 according to one embodiment of the invention. The gas passage has a hollow cathode cavity 604 on the downstream side 610. The downstream side 610 of the showerhead 600 faces the substrate and the susceptor during processing. The hollow cathode cavity 604 is drilled into the showerhead 600 from the downstream side 610. A top bore 608 is drilled into the showerhead 600 from the upstream side 612 of the showerhead. The top bore 602 may connect with the hollow cathode cavity 604 by an orifice 606. As shown in FIG. 6, the hollow cathode cavity has a diameter that gradually increases from the orifice 606 to the downstream side 610. Similarly, the top bore 608 has a diameter that increases from the orifice 606 to the upstream side 612 for a first distance and then is substantially constant. The orifice 606, because it has a smaller diameter than the top bore 608, creates a back pressure behind the showerhead 600 and thus, the amount of processing gas that passes through the showerhead 600 may be controlled to be substantially uniform across the showerhead 600.

The hollow cathode cavity 604 is shaped to permit plasma to ignite within the hollow cathode cavity 604. For the situation where the hollow cathode cavities 606 are present on the downstream side 610, but the top bore 608 has not been drilled from the upstream side 612, no gas will flow through the showerhead 600 at the location of the hollow cathode cavity 604 such as is shown in FIG. 5C in the corners. Even though no gas flows through the hollow cathode cavities 604 in the corners, processing gas that passes through other gas passages 602 will spread out in the processing chamber. The processing gas that reaches the hollow cathode cavities 604 in the corners may still be ignited into a plasma. Thus, the corner sections that extend out from a rectangular area of a showerhead may have the effect of not only providing an extended electrode, but also a plasma ignition location.

One reason to not drill the top bore 608 is to ensure the structural integrity of the showerhead 600. When the showerhead 600 has corner extensions that extend beyond the generally rectangular section of the showerhead 600, the structural integrity of the showerhead 600 may be compromised such that the showerhead 600 is too flimsy to support its own weight. A gas distribution showerhead 600 may have many thousand gas passages therethrough. Thus, the addition of additional gas passages in a corner extension may compromise the structural integrity of the showerhead 600.

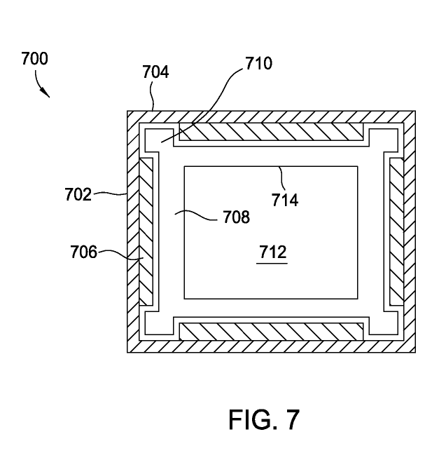

FIG. 7 is a schematic cross sectional view of a PECVD apparatus 700 according to another embodiment of the invention. The apparatus 700 has a generally rectangular shape with a plurality of walls 702 that join together at corners 704. Filler material 706 may be coupled to the walls 702 and extend therefrom between the corners 710 of the shadow frame 708 and the susceptor (not shown). The susceptor may have a shape that mirrors the shape of the shadow frame 708. The shadow frame 708 may have one or more corners 710 that extend beyond the generally rectangular area 714. The center of the rectangular area 714 may be opened to permit the substrate 712 to be exposed to the processing environment. The shadow frame 708, by having corners 710 that extend beyond the rectangular area 714, increases the anode area near the corners of the substrate 712 which may lead to more uniform material deposition.

By increasing the showerhead area, the susceptor area, and/or the shadow frame area, the anode and the electrode in a PECVD chamber may be optimized to permit uniform deposition of material onto a substrate. Thus, when depositing microcrystalline silicon, the corners of the substrate may have microcrystalline silicon deposited having the same properties as the microcrystalline silicon in other areas of the substrate. Additionally, the microcrystalline silicon may have a uniform thickness.

While the foregoing is directed to embodiments of the present invention, other and further embodiments of the invention may be devised without departing from the basic scope thereof, and the scope thereof is determined by the claims that follow.

1. A gas distribution showerhead, comprising:
a showerhead body having a generally rectangular shape, a first surface, a second surface opposite to the first surface, and a plurality of gas passages extending between the first surface and the second surface; and
one or more corner extension elements coupled to the showerhead body and extending from one or more corners of the showerhead body, the one or more corner extension elements having a third surface and a fourth surface opposite the third surface.

2. The gas distribution showerhead of claim 1, wherein the one or more corner extension elements has a bore formed in the fourth surface.

3. The gas distribution showerhead of claim 2, wherein the bore comprises a hollow cathode cavity.

4. The gas distribution showerhead of claim 1, wherein a gas passage extends between the third surface and the fourth surface.

5. The gas distribution showerhead of claim 4, wherein the gas passage has a hollow cathode cavity.

6. The gas distribution showerhead of claim 1, wherein the one or more corner extension elements has a rounded perimeter relative to the rectangular shaped showerhead body.

7. A plasma enhanced chemical vapor deposition apparatus, comprising:
a chamber body;
a substrate support disposed within the chamber body having a substrate support surface for receiving a substrate, the substrate support surface having a generally rectangular shape;
a gas distribution showerhead disposed in the chamber body opposite the substrate support, the gas distribution showerhead having a first surface facing the substrate support surface and a second surface opposite the first surface, the first surface generally mirrors the substrate support surface; and
one or more showerhead extension elements coupled to the gas distribution showerhead at one or more corners thereof.

8. The apparatus of claim 7, wherein the gas distribution showerhead and the one or more showerhead extension elements comprise a unitary body.

9. The apparatus of claim 7, wherein gas passages extend between the first surface and the second surface and wherein at least one gas passage has a hollow cathode cavity.

10. The apparatus of claim 7, wherein the one or more showerhead extension elements have a third surface and a fourth surface opposite the third surface and wherein gas passages extend between the third surface and the fourth surface.

11. The apparatus of claim 10, wherein at least one gas passage has a hollow cathode cavity.

12. The apparatus of claim 7, wherein the one or more showerhead extension elements have a third surface and a fourth surface opposite the third surface, wherein the fourth surface is substantially parallel to the first surface, and wherein the fourth surface has a hollow cathode cavity formed therein.

13. The apparatus of claim 7, further comprising a shadow frame disposed within the chamber body between the gas distribution showerhead and the substrate support, wherein the shadow frame has an outside perimeter that substantially matches the outside perimeter of the gas distribution showerhead and the one or more showerhead extensions collectively.

14. The apparatus of claim 7, further comprising a shadow frame disposed within the chamber body between the gas distribution showerhead and the substrate support, wherein the shadow frame has a corner that extends closer to the corner of the chamber body than any corner of the substrate support extends to any corner of the chamber body.

15. A plasma enhanced chemical vapor deposition apparatus, comprising:
a chamber body having a generally rectangular shape;
a substrate support disposed in the chamber body having a generally rectangular shape;
a gas distribution showerhead disposed in the chamber body opposite the susceptor; and
a shadow frame disposed in the chamber body between the substrate support and the gas distribution showerhead, the shadow frame having a main body that has a generally rectangular shape and one or more corner extension elements that extend from one or more corners of the main body.

16. The apparatus of claim 15, further comprising filler material disposed in the chamber body adjacent the substrate support and coupled to the chamber body, wherein the filler material substantially fills an area between two corner extension elements when viewed from above the substrate support.

17. The apparatus of claim 15, wherein the gas distribution showerhead has a perimeter that substantially mirrors the perimeter of the shadow frame.

18. The apparatus of claim 15, wherein the gas distribution showerhead has a first surface facing the substrate support and a second surface opposite the first surface and wherein the gas distribution showerhead has one or more gas passages extending between the second surface and the first surface.

19. The apparatus of claim 18, wherein at least one gas passage has a hollow cathode cavity.

20. The apparatus of claim 15, wherein the gas distribution showerhead comprises:
a showerhead body having a generally rectangular shape, a first surface, a second surface opposite to the first surface, and a plurality of gas passages extending between the first surface and the second surface; and
one or more corner extension elements coupled to the showerhead body and extending from one or more corners of the showerhead body, the one or more corner extension elements having a third surface and a fourth surface opposite the third surface, the one or more corner extension elements having a hollow cathode cavity formed in the fourth surface.
